(19) United States
(12) Patent Application Publication
(10) Pub. No.: US 2007/0285100 A1
(43) Pub. Date: Dec. 13, 2007

(54) Trailer mate circuit tester

(76) Inventor: Johnny Mack Hart, Alsip, IL (US)

Correspondence Address: Johnny M. Hart, Suite 205, 3837 W. 127th Street, Alsip, IL, 60803, US

(21) Appl. No.: 11/409,483

(22) Filed: Jun. 8, 2006

(51) Int. Cl. G01R 31/00

(52) U.S. Cl. 324/504

(57) ABSTRACT

A method for testing lighting systems in tractors and trailers. To use the tester to check small trailers; connect male cord from trailer to female connection on tester. Connect 12V power supply cord to power supply, connect power supply to tester to check lighting system. To use tester to check semi-trailers: connect tester to the 7-way female connection in the front of the semi-trailer. Connect 12V power supply cord to power supply, connect power supply to tester to check lighting system or Abs. To use tester to check truck or tractor: connect supply cord from truck or tractor to 7-way female connection on tester. No power supply required. Activate tractor switch on tester. You will now be able to test each lighting system on the truck or tractor. The LED light on tester will indicate if system is working properly or not.

### CROSS-REFERENCE TO RELATED APPLICATIONS

Not Applicable

### STATEMENT REGARDING FEDERALLY SPONSORED RESEARCH OR DEVELOPMENT

Not Applicable

### REFERENCE TO SEQUENCE LISTING, A TABLE, OR COMPUTER PROGRAM LISTING COMPACT DISC APPENDIX

Not Applicable

### BACKGROUND OF INVENTION

The concept of the trailer mate circuit tester unit is to make servicing and repairing any semi-tractor and trailer as well as small utility trailers lighting systems easier and less time consuming.

The trailer mate circuit tester can also be used to make installation of a new lighting system on a new or custom built trailer easier.

### BRIEF SUMMARY OF THE INVENTION

This Tester will be used to check the lighting systems on small utility trailers and full semi-trailers. It can also be used to check the out-put of the trailer supply cords from a road truck or tractor. This tester will produce fast, accurate light tests in a single walk-around. You check the lights, as well as the ABS, as they function in a controlled, easily recognizable sequence. This is far more meaningful than trying to test all lighting functions at once, and much faster than making multiple trips to the front of the trailer to flip switches. From start to finish, the whole test takes just 60 seconds, including set-up. The tester monitors all circuits simultaneously. Experienced technicians or beginning mechanics will be able to zoom right to the repair, skipping the sometimes unavoidable “educated guess”.

### BRIEF DESCRIPTION OF THE SEVERAL VIEWS OF THE DRAWINGS

FIG. 1: Shows the top of the trailer mate circuit tester control panel with indicator lights and control switches view thereof;

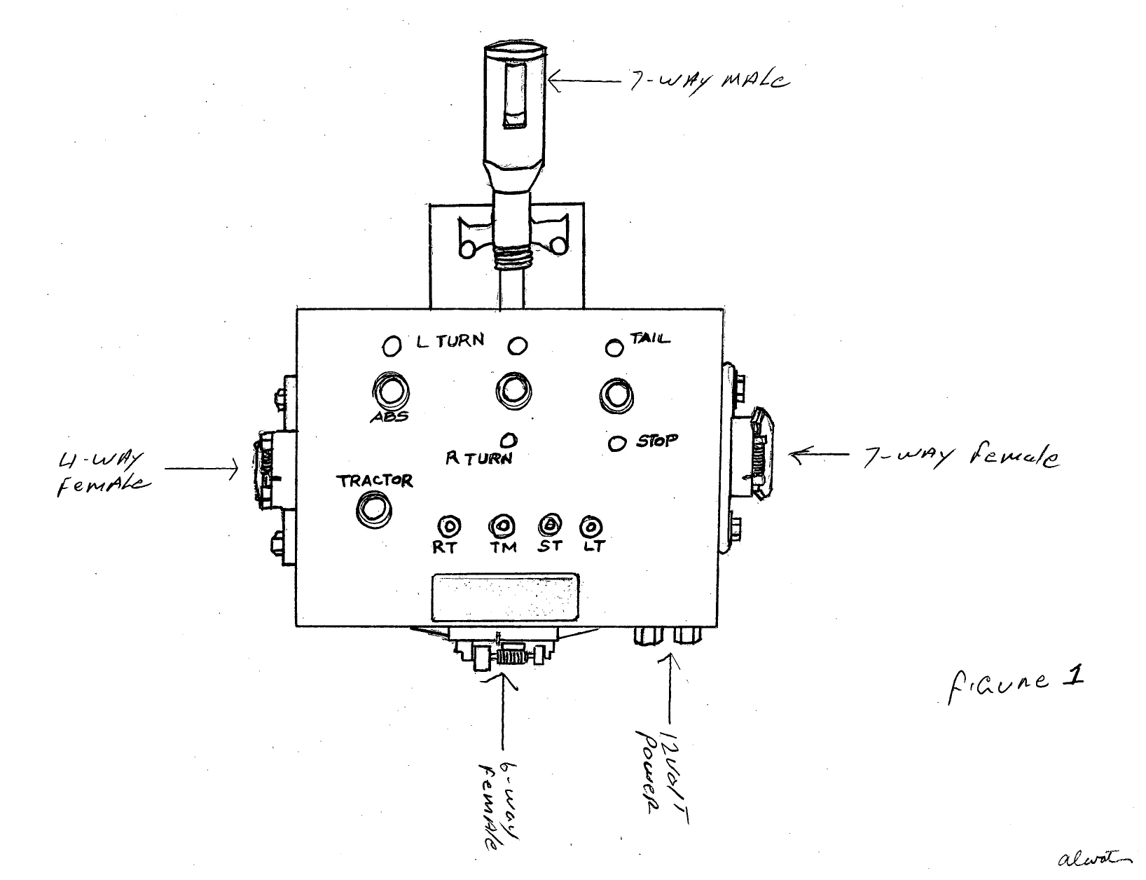

FIG. 2: Shows the right side of the trailer mate circuit tester 7-way female connection view thereof;

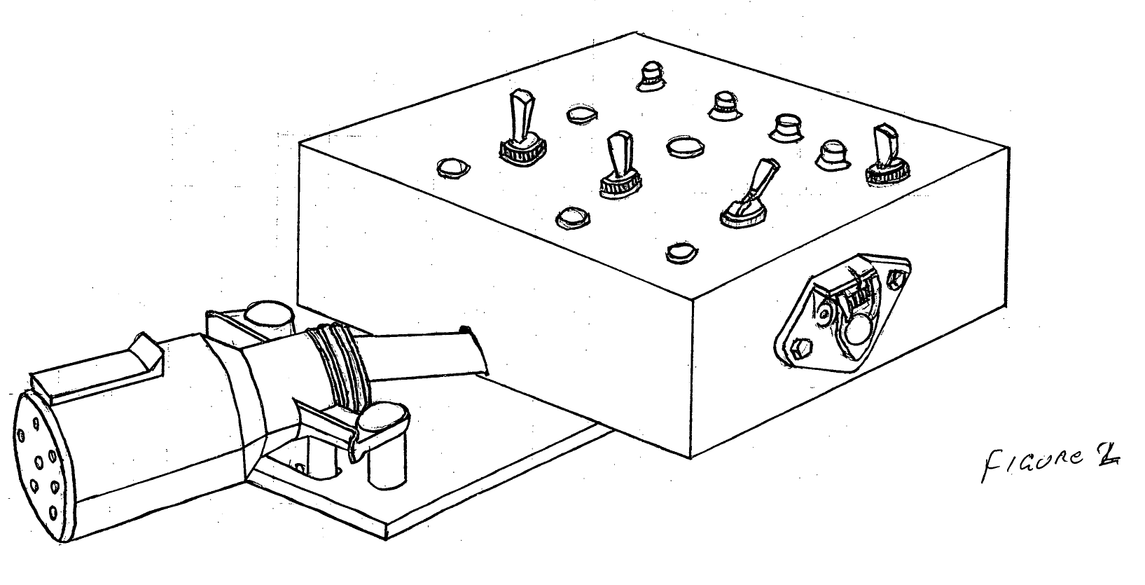

FIG. 3: Shows the left side of the trailer mate circuit tester 4-way female connection view thereof;

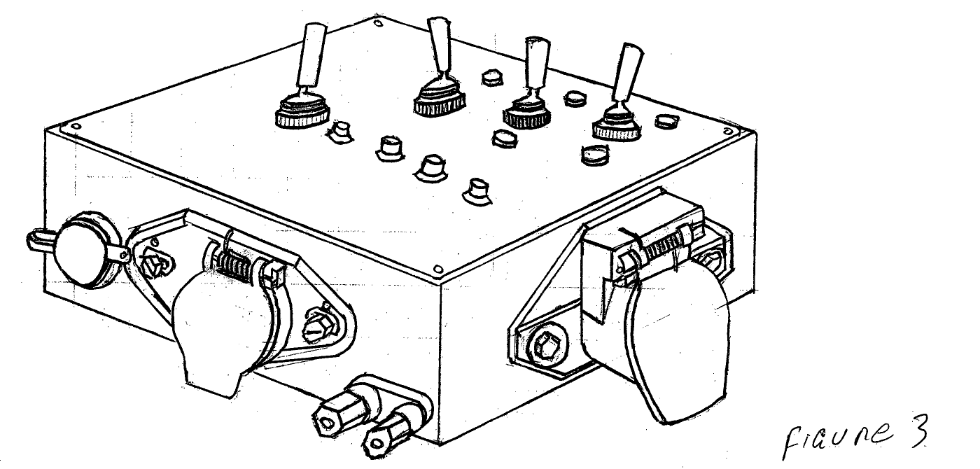

FIG. 4: Shows the rear of the trailer mate circuit tester 6-way female connection and the input power connection view thereof; and

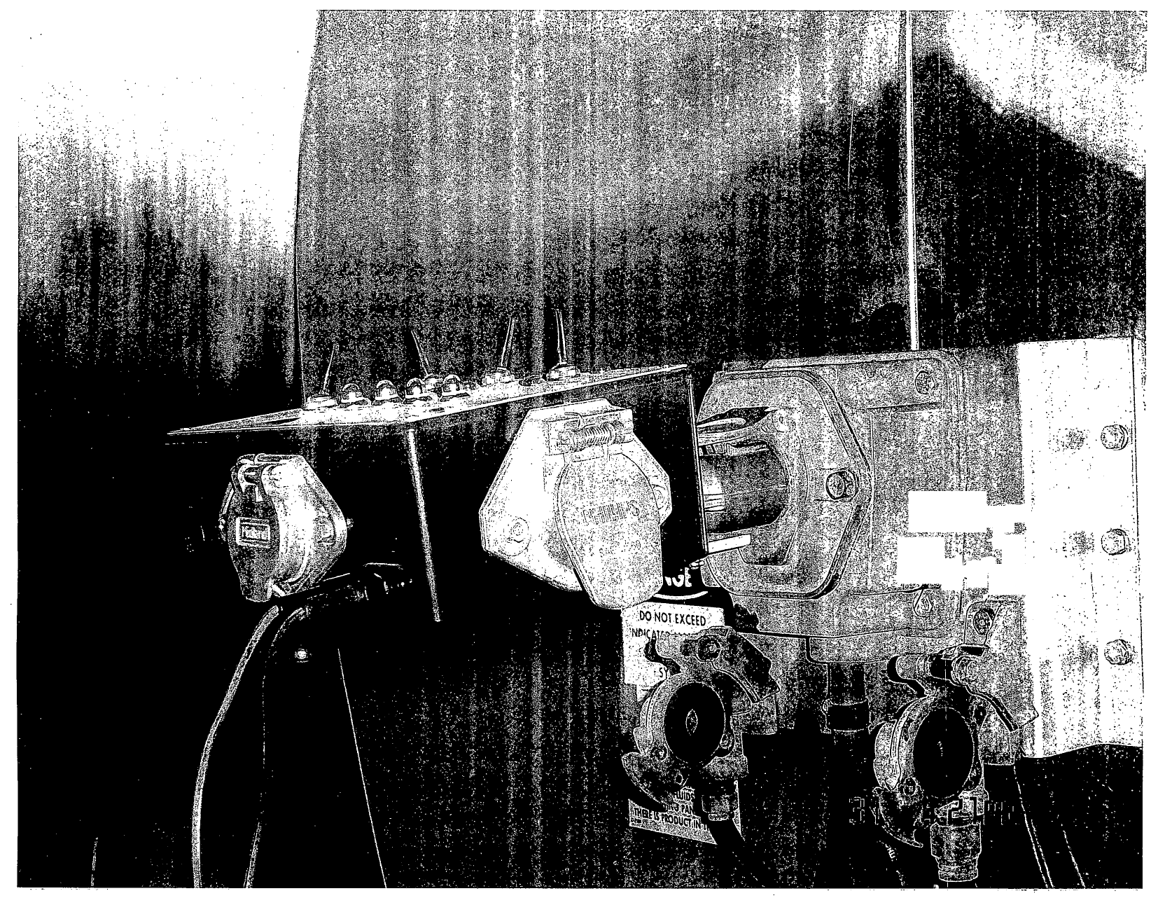

FIG. 5: Shows the front of the trailer mate circuit tester 7-way male connection view thereof.

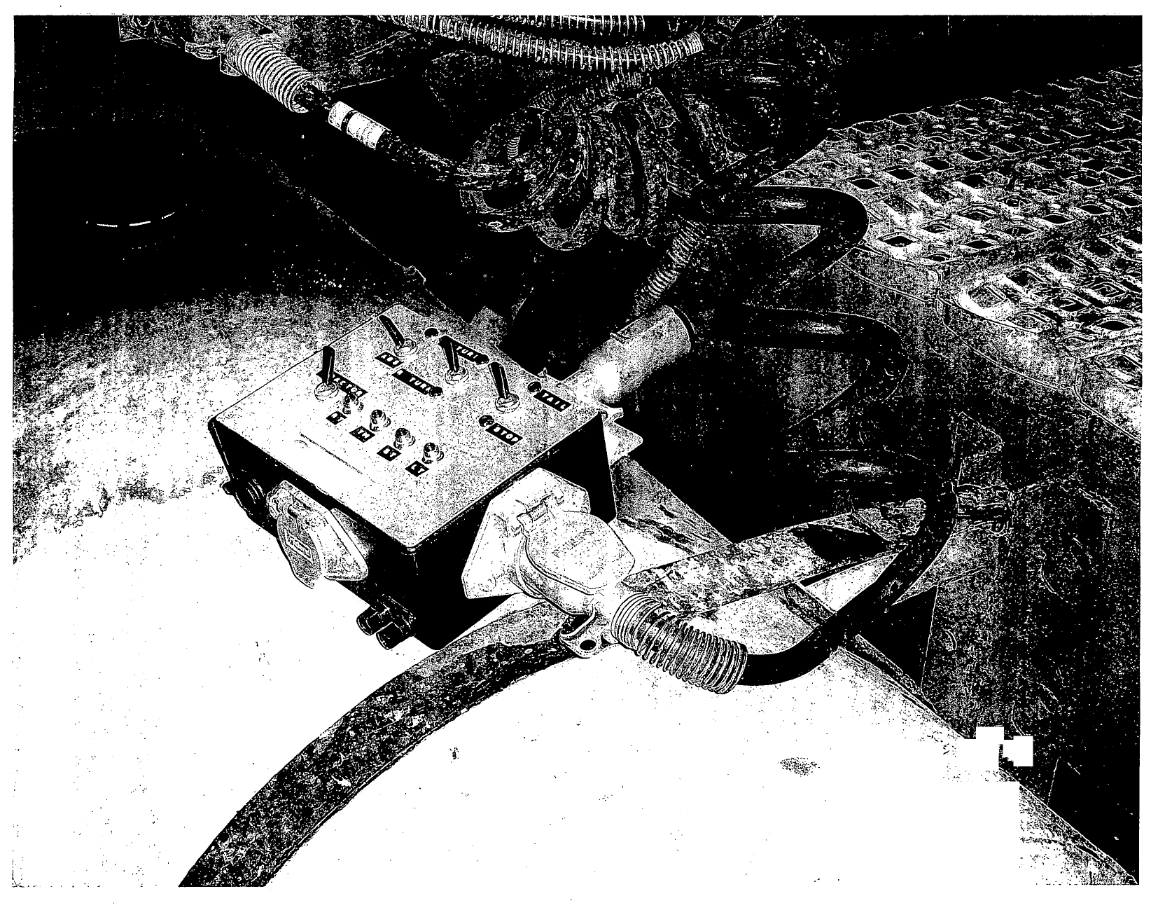

### DETAILED DESCRIPTION OF THE INVENTION

The tester comes with two power supply cords, one four way adapter and a remote cord for easy repairs and servicing.

The tester is made with a 7, 6 and 4 way female connection and a 7-way male connection to a 12 volt power connection. It has four toggle switches, nine indicator lights that show the function of each circuit. The control box is made of plastic ⅛″ thick, 3×5×½×8. The male connection support plate is made of ¼×4 aluminum plate with two ¼×1″ bolts to support the 7-way male connection. The interior of the tester consists of one nine post junction block, two heavy duty flashers, two 30 amp circuit breaker and 14 age wire. All wiring in the tester are crimped on.

The tester comes with two power supply cords, one four way adapter and a remote cord for easy repairs and servicing.

I claim:

1. The trailer mate circuit tester is for testing the lighting systems and anti-lock brake systems on trailers and tractors as described and shown.
